(19) United States
(12) Patent Application Publication
(10) Pub. No.: US 2026/0262472 A1
(43) Pub. Date: Sep. 3, 2026

(54) ELECTROSTATIC CHUCK, SUBSTRATE PROCESSING APPARATUS, AND SUBSTRATE PROCESSING METHOD

(71) Applicant: Tokyo Electron Limited, Tokyo (JP)

(72) Inventors: Einosuke TSUDA, Nirasaki-shi (JP); Satoshi TAKEDA, Nirasaki-shi (JP); Shunichi KUSAKA, Nirasaki-shi (JP); Yasuyuki KAGAYA, Nirasaki-shi (JP)

(21) Appl. No.: 19/657,081

(22) Filed: Apr. 24, 2026

Related U.S. Application Data
(63) Continuation of application No. PCT/JP2024/021159, filed on Jun. 11, 2024.

(30) Foreign Application Priority Data
Oct. 30, 2023 (JP) 2023-185753

(51) Int. Cl. H10P 72/72; C23C 16/458; H10P 72/00

(52) U.S. Cl. CPC H10P 72/722; C23C 16/4581; C23C 16/4586; H10P 72/0432

(57) ABSTRACT

An electrostatic chuck for electrostatically attracting a substrate includes: a first base having an upper surface on which the substrate is placed; and a second base disposed on a lower surface side of the first base, wherein the first base includes a plate-shaped member made of a composite material of metal and ceramics, and an insulating layer having insulating properties and formed in a layered structure on an upper surface of the plate-shaped member, and wherein the second base is made of a material having a coefficient of thermal expansion close to a coefficient of thermal expansion of the composite material.

### CROSS-REFERENCE TO RELATED APPLICATION

This application is a Bypass Continuation Application of PCT International Application No. PCT/JP2024/021159, filed on June 11, 2024 and designating the United States, the international application being based upon and claiming the benefit of priority from Japanese Patent Application No. 2023-185753, filed on October 30, 2023, the entire content of which is incorporated herein by reference.

### TECHNICAL FIELD

The present disclosure relates to an electrostatic chuck, a substrate processing apparatus, and a substrate processing method.

### BACKGROUND

In a process of manufacturing a semiconductor device, a semiconductor wafer serving as a substrate (hereinafter referred to as a "wafer") is subjected to film formation by chemical vapor deposition (CVD) or atomic layer deposition (ALD). This film formation process is performed by supplying a film formation gas when the wafer, which is placed on a stage in a processing chamber, is heated to a predetermined temperature by a heater provided in the stage. In addition, there is known a film formation apparatus in which a peripheral portion of the wafer on the stage is pressed against the stage by a ring-shaped fixing member to fix the wafer to the stage when performing the film formation process (see Patent Document 1).

### [Prior Art Document]

### Patent Document

Patent Document 1: Japanese Patent No. 5699425

### SUMMARY

Some embodiments of the present disclosure provide an electrostatic chuck for electrostatically attracting a substrate that includes: a first base having an upper surface on which the substrate is placed; and a second base disposed on a lower surface side of the first base, wherein the first base includes a plate-shaped member made of a composite material of metal and ceramics, and an insulating layer having insulating properties and formed in a layered structure on an upper surface of the plate-shaped member, and wherein the second base is made of a material having a coefficient of thermal expansion close to a coefficient of thermal expansion of the composite material.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a substrate processing apparatus (electrostatic chuck) according to a first embodiment of a technology of the present disclosure.

FIG. 2 is a schematic enlarged cross-sectional view illustrating an example of a region [A] surrounded by a dash-double-dotted line in FIG. 1.

FIGS. 3A and 3B are schematic enlarged cross-sectional views illustrating an example of an electrostatic chuck according to a second embodiment of the technology of the present disclosure.

FIG. 4 is a diagram illustrating an example of a simulation result of a gas flow.

FIG. 5 is a schematic cross-sectional view illustrating an example of a substrate processing apparatus (electrostatic chuck) according to a third embodiment of the technology of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

As disclosed above, in a technology of Patent Document 1, when performing a film formation process, a peripheral portion of a wafer on a stage is pressed and fixed to the stage by a ring-shaped fixing member. However, in the wafer used in the film formation process, it is preferable for a contact area between the wafer and the fixing member or the like to be minimized. In recent years, fixing the wafer to the stage without pressing the wafer with the fixing member has been desired.

In the technology of Patent Document 1, only the peripheral portion of the wafer is pressed against the stage by the fixing member, and other portions are merely placed on the stage by a weight of the wafer. Therefore, the wafer and the stage may be spaced further apart than expected, which may make it difficult to control a temperature of the wafer by the heater provided in the stage.

Hereinafter, embodiments of a technology of the present disclosure will be described with reference to the drawings. However, configurations described in the following embodiments are merely examples and the present disclosure is not limited to such configurations. For example, each portion included in the configurations can be replaced with any other portion that can perform the same function. Further, any component may be added.

### First Embodiment

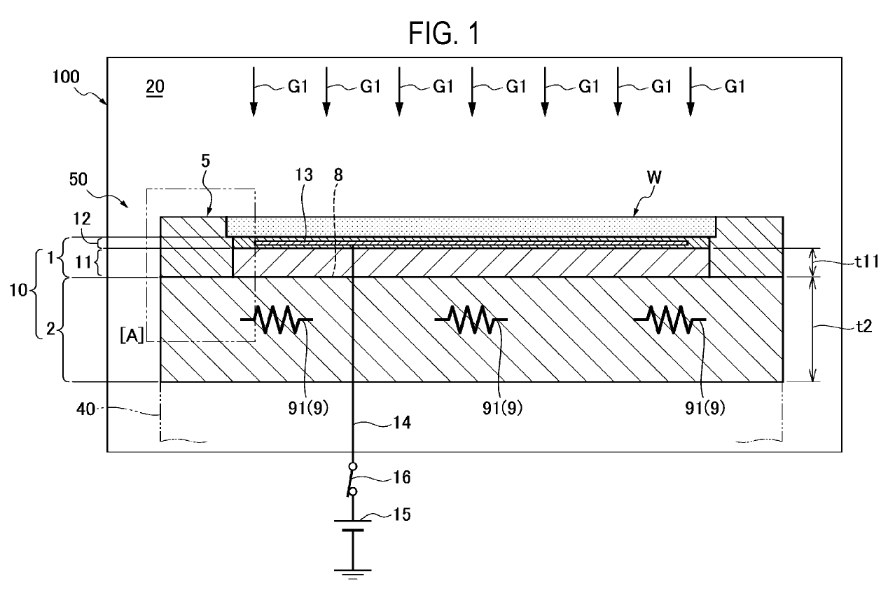

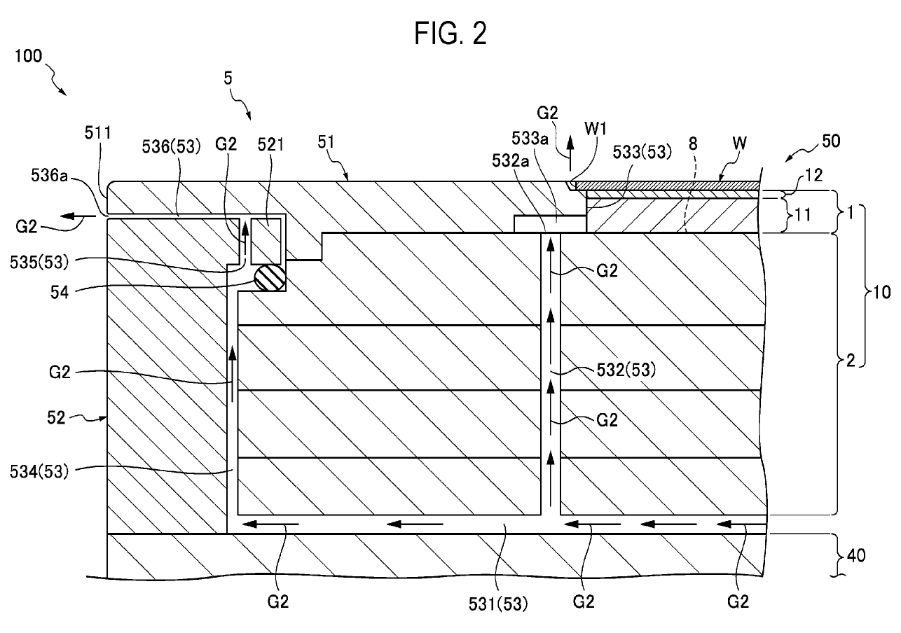

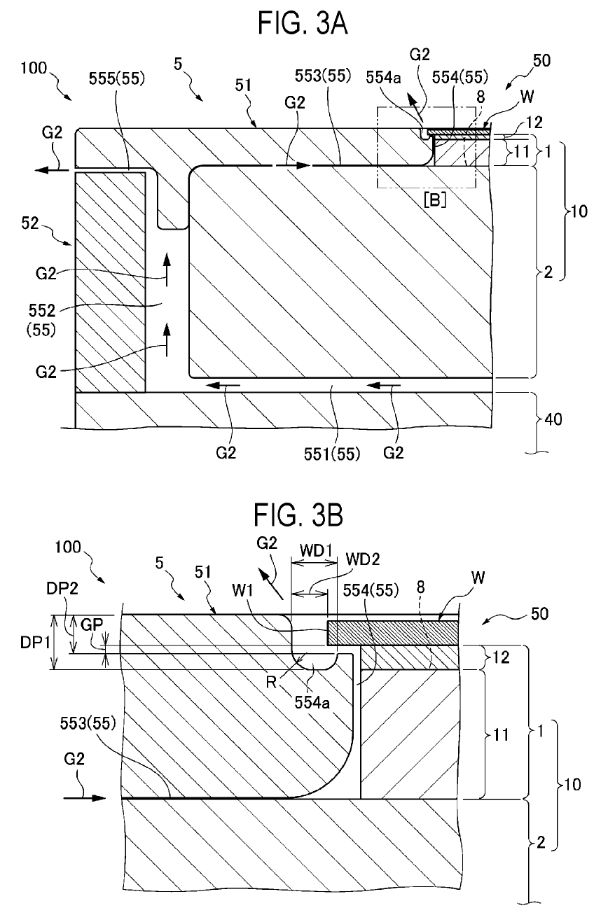

Hereinafter, a first embodiment will be described with reference to FIGS. 1 and 2. FIG. 1 is a schematic cross-sectional view illustrating an example of a substrate processing apparatus (electrostatic chuck) according to the first embodiment of the technology of the present disclosure. FIG. 2 is a schematic enlarged cross-sectional view of a region [A] surrounded by a dash-double-dotted line in FIG. 1. In FIGS. 1 and 2 (and similarly in FIGS. 3A to 5), in order to facilitate understanding, a vertical direction (thickness direction or height direction) of the substrate processing apparatus is schematically illustrated in an exaggerated manner compared to a horizontal direction, and a ratio of a vertical length to a horizontal length differs from the actual ratio.

A substrate processing apparatus 100 shown in FIG. 1 is an apparatus that performs a film formation process (substrate processing method) on a semiconductor wafer W serving as a substrate (hereinafter referred to as a "wafer W") in a manufacturing process of a semiconductor device. The film formation process is not particularly limited, and for example, a film formation process by CVD or the like can be used. Using CVD, a ruthenium (Ru) film, which is a metal film, is formed on a surface of the wafer W. The substrate processing apparatus 100 includes an electrostatic chuck 10 and a processing chamber 20 that accommodates the electrostatic chuck 10. The electrostatic chuck 10 is a device that electrostatically attracts the wafer W. The processing chamber 20 is a device that performs the film formation process on the wafer W while the wafer W is electrostatically attracted to the electrostatic chuck 10. An interior of the processing chamber 20 is adjusted to a vacuum atmosphere at a desired pressure by a pressure adjuster (not shown), and ruthenium which serves as a process gas (film formation gas) G1 is supplied by a ruthenium supplier (not shown) to the processing chamber 20. By performing temperature control on the wafer W in such a state, a ruthenium film can be formed on the surface of the wafer W. The processing chamber 20 is grounded.

As shown in FIG. 1, the electrostatic chuck 10 is a stack including a first base 1 having a disk shape (plate shape) and having an upper surface on which the wafer W is placed and a second base 2 having a disk shape (plate shape) and disposed concentrically with the first base 1 on a lower surface side of the first base 1. The electrostatic chuck 10 is supported on a support 40. In the substrate processing apparatus 100, a stage 50 on which the wafer W is placed is constituted by the electrostatic chuck 10 and the support 40.

The first base 1 includes a plate-shaped member 11 and an insulating layer 12 formed in a layered structure on an upper surface of the plate-shaped member 11. The plate-shaped member 11 is made of a composite material of metal and ceramics (metal matrix composites (MMC)). The composite material is not particularly limited, and for example, a composite material of aluminum and silicon carbide or the like can be used. The insulating layer 12 is made of an insulating material having insulating properties. The insulating material is not particularly limited, and for example, aluminum oxide (alumina) or the like can be used. An electrode 13 is provided inside the insulating layer 12, that is, in the middle of the insulating layer 12 in the thickness direction. The electrode 13 is connected to a DC power supply 15 via a conductive wire 14. Accordingly, a voltage is applied to the electrode 13. A negative terminal side of the DC power supply 15 is preferably grounded. A switch 16 is provided in the conductive wire 14. The electrostatic chuck 10 having such a configuration is a Johnson-Rahbek-type electrostatic chuck, which is capable of attracting the wafer W by Johnson-Rahbek force. Specifically, by turning on the switch 16, the wafer W and the electrode 13 function as opposing electrodes of a capacitor and polarization occurs across the wafer W and the electrode 13 with the insulating layer 12 interposed therebetween. As a result, the entire surface of the wafer W, that is, an entire lower surface (back surface), can be attracted to the electrostatic chuck 10. A method of forming the insulating layer 12 is not particularly limited, and for example, a method in which aluminum oxide, which is a constituent material of the insulating layer 12, is thermally sprayed onto an upper surface of the plate-shaped member 11 in a state where the electrode 13 is disposed on the upper surface of the plate-shaped member 11 may be used.

The second base 2 is made of a metal material having a thermal expansion rate (coefficient of thermal expansion) close to that of the composite material constituting the plate-shaped member 11 of the first base 1. The metal material is not particularly limited, and for example, any one of titanium, aluminum oxide, a copper-tungsten alloy, a copper-molybdenum alloy, and chromium can be used. However, titanium is preferably used. A coefficient of thermal expansion of the composite material constituting the plate-shaped member 11 is, for example, 3×10⁻⁶ to 14×10⁻⁶ [/degree C] in a case where the composite material is made of aluminum and silicon carbide, although the coefficient of thermal expansion of the composite material varies depending on contents of each component, that is, a mixing ratio. In contrast, a coefficient of thermal expansion of titanium is 8.4×10⁻⁶ to 8.6×10⁻⁶ [/degree C]. In the present embodiment, the expression "the composite material constituting the plate-shaped member 11 and the metal material constituting the second base 2 have close coefficients of thermal expansion" means that "there is an overlapping portion between the coefficient of thermal expansion of the composite material and the coefficient of thermal expansion of the metal material" but is not limited thereto. In the coefficients of thermal expansion described above, the overlapping portion between the coefficient of thermal expansion of the composite material and the coefficient of thermal expansion of the metal material is 8.4×10⁻⁶ to 8.6×10⁻⁶ [/degree C]. Due to a high availability, titanium is preferred as a constituent material of the second base 2. A thickness t2 of the second base 2 is thicker than a thickness t11 of the plate-shaped member 11 of the first base 1. The thickness t11 is preferably, for example, 5 mm or more and 20 mm or less, and more preferably, 12 mm or more and 15 mm or less. In this case, the thickness t2 is preferably 1.5 times or more and 20 times or less the thickness t11, and more preferably, 5 times or more and 10 times or less. The number of second bases 2 is one in the configuration shown in FIG. 1, but is not limited thereto and may be, for example, plural.

The first base 1 and the second base 2 are bonded to each other via a bonding material 8. A constituent material of the bonding material 8 is not particularly limited, and for example, aluminum or the like can be used. In a case where the bonding material 8 is made of aluminum, the first base 1 and the second base 2 are pressed toward each other while being heated, with an aluminum sheet serving as the bonding material 8 interposed therebetween. As a result, the aluminum constituting the bonding material 8 is melted, and the first base 1 and the second base 2 are bonded to each other. Thus, when the film formation process is performed on the wafer W, heat from a heating portion 9 provided in the second base 2 is transmitted to the wafer W through the first base 1 without excess or deficiency. In the present embodiment, the first base 1 and the second base 2 are bonded to each other with the bonding material 8 interposed therebetween. However, the present disclosure is not limited thereto, and for example, the first base 1 and the second base 2 may be bonded by a method using screw fastening, a method using a clamp member, or the like.

The heating portion 9 for heating the wafer W is provided in the second base 2. The heating portion 9 is constituted by a plurality of heaters 91 embedded in the second base 2. Each heater 91 generates heat by being energized. The heaters 91 are distributed in the horizontal direction (left-right direction in FIG. 1). The heat generated by each heater 91 is sequentially transmitted via the second base 2 and the first base 1 to the wafer W, which is electrostatically attracted to the first base 1. A temperature of the electrostatic chuck 10 (each heater 91), while varying depending on the film formation process, is preferably 150 degrees C or higher and 250 degrees C or lower and, more preferably, 150 degrees C or higher and 160 degrees C or lower. Although each heater 91 is embedded in the second base 2 in the present embodiment, each heater 91 may be embedded in the plate-shaped member 11 of the first base 1. However, a process of embedding each heater 91 is easier when performed on the second base 2 made of the metal material than when performed on the plate-shaped member 11 made of the composite material. Therefore, it is preferable to embed each heater 91 in the second base 2.

When performing the film formation process on the wafer W at a high temperature with the electrostatic chuck 10 having the configuration described above, the film formation process can be performed in a state in which the wafer W is held in close contact with the electrostatic chuck 10 by electrostatic attraction. Accordingly, it is possible to omit other members such as an annular clamp ring that are disposed above an electrostatic chuck in the related art and presses to fix the wafer W. Therefore, in the electrostatic chuck 10, the wafer W can be sufficiently fixed without bringing such other members into contact with an upper surface of the wafer W. As a result, the film formation process on the wafer W can be performed stably. In some cases, avoiding contact between such other members and the upper surface of the wafer W may be preferred during the film formation process. For this reason, electrostatic attraction by the electrostatic chuck 10 is preferable in the film formation process.

As described above, the interior of the processing chamber 20 is adjusted to a vacuum atmosphere at a desired pressure, and ruthenium, which is the process gas G1, is supplied thereto. By controlling the temperature of the wafer W in this state, a ruthenium film can be formed on the surface of the wafer W. Since ruthenium is relatively sensitive to temperature changes, it is preferable to control the temperature of the entire wafer W during film formation as accurately as possible. Therefore, the electrostatic chuck 10 is configured to include the plate-shaped member 11 (first base 1) made of the composite material. Accordingly, when heat from each heater 91 is transmitted to the plate-shaped member 11, the heat is transmitted to the wafer W via the insulating layer 12 while being uniformly diffused in the plate-shaped member 11 with respect to the wafer W. In this way, the plate-shaped member 11 has a heat diffusion function. As a result, the temperature of the entire wafer W during film formation can be controlled as accurately as possible, and therefore, the ruthenium film can be formed uniformly. In this case, temperature variations in the surface of the wafer W during film formation are typically suppressed within a range of ±1 degree C. Here, a case in which the plate-shaped member 11 is omitted is considered. In this case, the insulating layer 12 is provided on the second base 2 and the heat from each heater 91 is transmitted to the wafer W via the insulating layer 12 without being distributed as uniformly in the second base 2 as in the plate-shaped member 11. With such transmission, it becomes difficult to accurately control the temperature of the entire wafer W during film formation, and as a result, there is a concern of non-uniform formation of the ruthenium film.

In the electrostatic chuck 10, both the first base 1 and the second base 2 undergo thermal deformation due to the heat from each heater 91. However, since the coefficients of thermal expansion of the first base 1 and the second base 2 are close to each other, the first base 1 and the second base 2 tend to undergo the same thermal deformation. As a result, it is possible to prevent or suppress the occurrence of warpage in the electrostatic chuck 10 or to maintain a bonded state between the first base 1 and the second base 2, thereby enabling stable heating of the wafer Won the electrostatic chuck 10. The coefficient of thermal expansion of aluminum oxide is 7.0×10⁻⁶ to 7.7×10⁻⁶ [/degree C]. When the insulating layer 12 is made of aluminum oxide, the insulating layer 12 has a coefficient of thermal expansion that is close to that of the plate-shaped member 11. Accordingly, even when the insulating layer 12 is heated by the heat from each heater 91, a state in which the insulating layer 12 is formed on the plate-shaped member 11 can be maintained, that is, the insulating layer 12 can be prevented from peeling or cracking from the plate-shaped member 11.

As shown in FIG. 2, the electrostatic chuck 10 includes a gas discharger (gas discharge system) 5 that discharges a film formation suppressing gas G2 for suppressing film formation on a desired portion. In the present embodiment, targets for suppression of film formation include a peripheral portion W1 of the wafer W and a peripheral portion 511 of a first flow controller 51 of the gas discharger 5, which will be described later. The film formation suppressing gas G2 is not particularly limited, and for example, carbon monoxide (CO) gas can be used. The gas discharger 5 is connected to a gas supply source (not shown) that supplies the film formation suppressing gas G2. The gas discharger 5 includes the first flow controller (flow controller) 51 provided on an upper surface of the second base 2, and a second flow controller 52 provided on a side surface of the second base 2. The first flow controller 51 is a member having a flat annular shape that is disposed concentrically with the second base 2. The second flow controller 52 is a member having an annular shape along a circumferential direction of the side surface of the second base 2. The first flow controller 51 and the second flow controller 52 are members that control a flow of the film formation suppressing gas G2. Constituent materials of the first flow controller 51 and the second flow controller 52 are not particularly limited, and for example, a material substantially the same as the second base 2 can be used.

The gas discharger 5 includes a flow path 53 through which the film formation suppressing gas G2 passes. The flow path 53 is constituted by a flow path 531, a flow path 532, a flow path 533, a flow path 534, a flow path 535, and a flow path 536. The flow path 531 is formed between the second base 2 and the support 40. The flow path 532 communicates with the flow path 531 and is formed so as to penetrate the second base 2 in the vertical direction (thickness direction). The flow path 533 communicates with the flow path 532 and is formed between the first flow controller 51 and the first base 1. The flow path 534 communicates with the flow path 531 and is formed between the second flow controller 52 and the second base 2. The flow path 535 communicates with the flow path 534 and is formed so as to penetrate, in the vertical direction (thickness direction), a protruding portion 521 of the second flow controller 52 that protrudes toward the second base 2. The flow path 536 communicates with the flow path 535 and is formed between the first flow controller 51 and the second flow controller 52.

The flow path 532 includes a first discharge port (discharge port) 532a configured to open on the upper surface of the second base 2. The first discharge port 532a discharges the film formation suppressing gas G2 toward the peripheral portion W1 of the wafer Won the first base 1 via the flow path 533. Accordingly, the film formation suppressing gas G2 can come into contact with the edge portion W1 of the wafer W prior to the process gas G1, thereby preventing or suppressing contact between the process gas G1 and the peripheral portion W1. As a result, formation of the ruthenium film at the peripheral portion W1 can be suppressed. Since the lower surface (back surface) of the wafer W is in close contact with the electrostatic chuck 10, formation of the ruthenium film on the lower surface of the wafer W is also suppressed. The flow path 533 can control the flow of the film formation suppressing gas G2 discharged from the first discharge port 532a. Specifically, the flow path 533 includes, at an upstream side of the flow path 533, a relief portion 533a that reduces a flow velocity of the film formation suppressing gas G2 and directs the film formation suppressing gas G2 in a direction away from the wafer W. The relief portion 533a is constituted by an annular groove formed on a lower surface of the first flow controller 51. A depth of the groove constituting the relief portion 533a is constant. By providing such a relief portion 533a, the film formation suppressing gas G2 discharged from the first discharge port 532a is discharged uniformly over as wide a range as possible with respect to the peripheral portion W1 of the wafer W. As a result, a film formation suppressing effect of the film formation suppressing gas G2 on the peripheral portion W1 is enhanced.

The flow path 536 includes a second discharge port 536a that discharges the film formation suppressing gas G2 toward the peripheral portion 511 of the first flow controller 51. Accordingly, the film formation suppressing gas G2 can come into contact with the peripheral portion 511 of the first flow controller 51 prior to the process gas G1, thereby preventing or suppressing contact between the process gas G1 and the peripheral portion 511. As a result, formation of a ruthenium film at the peripheral portion 511 can be suppressed. The film formation suppressing gas G2 discharged from the second discharge port 536a can also suppress formation of the ruthenium film on a side surface of the second flow controller 52. The second flow controller 52 is configured to be detachable from the second base 2, for example, by screw fastening or the like. Accordingly, even when the ruthenium film is formed on the side surface of the second flow controller 52, the second flow controller 52 can be detached and cleaned to remove the ruthenium film. Alternatively, the second flow controller 52 can be replaced with a new second flow controller 52.

As shown in FIG. 2, the gas discharger 5 includes a ring member 54 disposed concentrically between the protruding portion 521 of the second flow controller 52 and the second base 2. The ring member 54 is made of an elastic material such as various rubber materials or various thermoplastic elastomers and is disposed in a compressed state between the second flow controller 52 and the second base 2. In the present embodiment, a temperature of the support 40 is controlled to, for example, 80 degrees C, at which suppression of film formation is possible. The second flow controller 52 is configured to be detachable from the support 40, for example, by screws fastening or the like. A temperature of the second flow controller 52 is also controlled to 80 degrees C, which is substantially the same as the temperature of the support 40. In contrast, the temperature of the electrostatic chuck 10 is controlled to, for example, 155 degrees C. The ring member 54, together with the flow path 531 and the flow path 534, can prevent heat of the electrostatic chuck 10 from being dissipated to the second flow controller 52 or the support 40. As a result, the temperature of the electrostatic chuck 10 can be stably maintained at 155 degrees C. Thus, the ring member 54 functions as a heat-insulating member together with the flow path 531 and the flow path 534.

Although not shown, the electrostatic chuck 10 is provided with a coolant flow path through which a coolant passes, a thermocouple that detects the temperature of the electrostatic chuck 10, or the like. Although also not shown, the electrostatic chuck 10 is also provided with a plurality of lift pins supported so as to be raised and lowered, that is, capable of moving up and down relative to the electrostatic chuck 10. When loading the wafer W into the processing chamber 20, the wafer W can be supported on the lift pins in a state in which the lift pins protrude from a surface of the electrostatic chuck 10. The lift pins then descend while supporting the wafer W, thereby enabling film formation on the wafer W on the electrostatic chuck 10. When unloading the wafer W from the processing chamber 20 after the film formation process, the lift pins are caused to protrude again from the surface of the electrostatic chuck 10, and the wafer W is supported on the lift pins. In this state, the wafer W can be unloaded.

### Second Embodiment

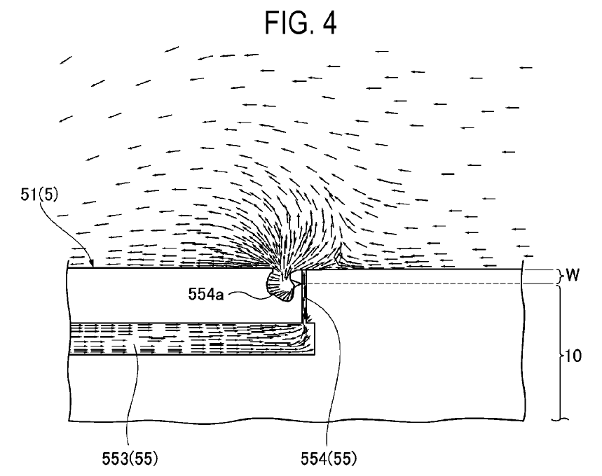

Hereinafter, a second embodiment will be described with reference to FIGS. 3A to 4, focusing mainly on differences from the above-described embodiment, and description of the same matters will be omitted. The present embodiment is the same as the first embodiment except that a configuration (shape) of flow paths of the gas discharger is different. FIGS. 3A and 3B are schematic enlarged cross-sectional views illustrating an example of an electrostatic chuck according to the second embodiment of the technology of the present disclosure. FIG. 3B is an enlarged view of a region [B] surrounded by a dash-double-dotted line in FIG. 3A. FIG. 4 is a diagram illustrating an example of a simulation result of a gas flow.

As shown in FIG. 3A, in the present embodiment, the gas discharger 5 includes a flow path 55 through which the film formation suppressing gas G2 passes. The flow path 55 is constituted by a flow path 551, a flow path 552, a flow path 553, a flow path 554, and a flow path 555. The flow path 551 is formed between the second base 2 and the support 40 and has a function substantially the same as that of the flow path 531 of the flow path 53 in the first embodiment. The flow path 552 communicates with the flow path 551, is formed between the second flow controller 52 and the second base 2 and has a function substantially the same as that of the flow path 534 of the flow path 53 in the first embodiment. The flow path 553 communicates with the flow path 552 and is formed between the first flow controller 51 and the second base 2. The flow path 554 communicates with the flow path 553, is formed between the first flow controller 51 and the first base 1 and has a function substantially the same as that of the flow path 533 of the flow path 53 in the first embodiment. The flow path 555 communicates with the flow path 552, is formed between the first flow controller 51 and the second flow controller 52 and has a function substantially the same as that of the flow path 536 of the flow path 53 in the first embodiment.

As shown in FIG. 3B, the flow path 554 includes, at a downstream side of the flow path 554, a relief portion 554a that reduces the flow velocity of the film formation suppressing gas G2 and directs the film formation suppressing gas G2 in a direction away from the wafer W. The relief portion 554a is constituted by an annular groove formed on an upper surface of the first flow controller 51. A depth of the groove constituting the relief portion 554a changes in two stages (stepwise). A depth DP1 of the deepest portion is preferably 1.5 mm or more and 3.0 mm or less and, more preferably, 1.5 mm or more and 2.0 mm or less. A depth DP2 of the shallowest portion is preferably 0.8 mm or more and 1.5 mm or less and, more preferably, 0.8 mm or more and 1.2 mm or less. In the shallowest portion, a gap is formed between the groove and the wafer W, and a size GP of the gap is preferably 0.2 mm or more and 0.5 mm or less and, more preferably, 0.2 mm or more and 0.3 mm or less. A width WD1 of the deepest portion is preferably 1 mm or more and 2 mm or less and, more preferably, 1 mm or more and 1.5 mm or less. A distance WD2 from a side wall of the relief portion 554a to a peripheral portion W1 of the wafer W is preferably 0.5 mm or more and 5 mm or less and, more preferably, 1 mm or more and 3 mm or less. A bottom portion of the deepest portion is rounded, and a radius R thereof is preferably 0.2 mm or more and 0.5 mm or less and, more preferably, 0.4 mm or more and 0.5 mm or less.

FIG. 4 is a diagram illustrating an example of a simulation result of a gas flow in and around the relief portion 554a. The gas includes the process gas G1 or the film formation suppressing gas G2. As shown in FIG. 4, it can be seen that, in an upper peripheral region of the wafer W, the gas is directed away from the wafer W. This confirms that the effect of the relief portion 554a is achieved and that film formation on the peripheral portion W1 of the wafer W is prevented.

### Third Embodiment

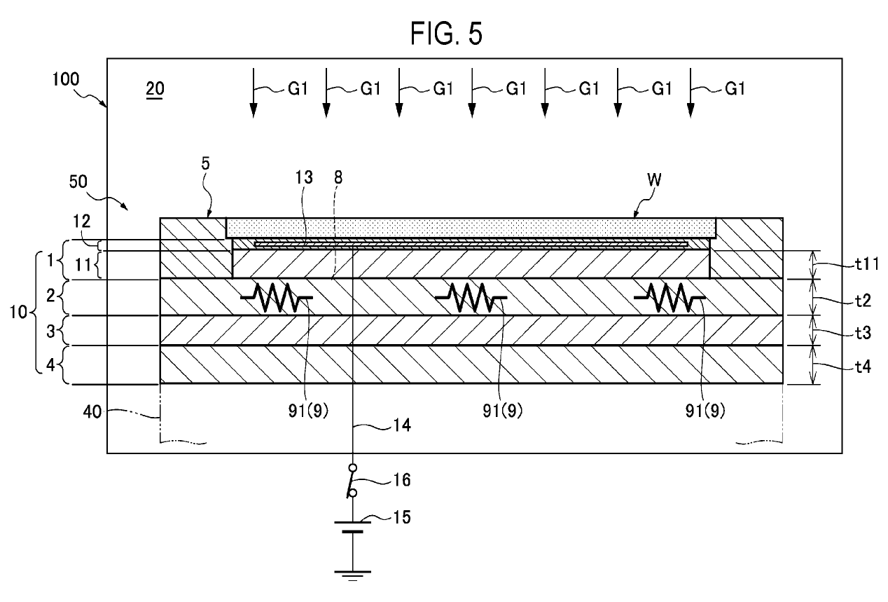

Hereinafter, a third embodiment will be described with reference to FIG. 5, focusing mainly on differences from the above-described embodiments, and description of the same matters will be omitted. The present embodiment is the same as the first embodiment except that a stacked structure of the electrostatic chuck is different. FIG. 5 is a schematic cross-sectional view illustrating an example of a substrate processing apparatus (electrostatic chuck) according to the third embodiment of the technology of the present disclosure.

As shown in FIG. 5, in the present embodiment, the electrostatic chuck 10 includes the first base 1 and the second base 2 and further includes a third base 3 and a fourth base 4 configured as a stack. The third base 3 is plate-shaped and is disposed on a lower surface side of the second base 2. The third base 3 is made of a composite material that is substantially the same as that of the plate-shaped member 11. The fourth base 4 is plate-shaped and is disposed on a lower surface side of the third base 3. The fourth base 4 is made of a metal material that is substantially the same as that of the second base 2, that is, the metal material having the coefficient of thermal expansion close to that of the composite material constituting the plate-shaped member 11. For bonding between the second base 2 and the third base 3 and for bonding between the third base 3 and the fourth base 4, an aluminum bonding material can be used in substantially the same manner as for bonding between the first base 1 and the second base 2. With such a stacked structure, even when the first base 1 to the fourth base 4 undergo thermal deformation, differences in thermal expansion among the bases are alleviated, thereby preventing or suppressing warpage of the electrostatic chuck 10. As a result, the wafer W on the electrostatic chuck 10 can be heated stably. Regarding thickness relationships among the respective bases, in the configuration shown in FIG. 5, the thickness t11 of the plate-shaped member 11 and a thickness t3 of the third base 3 are the same, and the thickness t2 of the second base 2 and a thickness t4 of the fourth base 4 are the same, but the present disclosure is not limited thereto.

While the exemplary embodiments of the present disclosure have been described, the present disclosure is not limited to the above-described embodiments and various changes and modifications are possible within the scope of the present disclosure.

According to the present disclosure in some embodiments, it is possible to sufficiently fix a substrate without bringing another member into contact with an upper surface of the substrate and to accurately perform temperature control of the substrate, when performing a process on the substrate, for example, under high-temperature conditions.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An electrostatic chuck for electrostatically attracting a substrate, comprising:
a first base having an upper surface on which the substrate is placed; and
a second base disposed on a lower surface side of the first base,
wherein the first base includes a plate-shaped member made of a composite material of metal and ceramics, and an insulating layer having insulating properties and formed in a layered structure on an upper surface of the plate-shaped member, and
wherein the second base is made of a material having a coefficient of thermal expansion close to a coefficient of thermal expansion of the composite material.

2. The electrostatic chuck of claim 1, wherein the composite material is a composite material of aluminum and silicon carbide.

3. The electrostatic chuck of claim 1, wherein the second base is made of any one of titanium, a copper-tungsten alloy, a copper-molybdenum alloy, and chromium.

4. The electrostatic chuck of claim 1, wherein the first base and the second base are bonded via a bonding material.

5. The electrostatic chuck of claim 4, wherein the bonding material is made of aluminum.

6. The electrostatic chuck of claim 1, wherein the insulating layer is made of aluminum oxide.

7. The electrostatic chuck of claim 1, wherein an electrode to which a voltage is applied when electrostatically attracting the substrate is provided inside the insulating layer.

8. The electrostatic chuck of claim 1, further comprising a gas discharger including a discharge port configured to discharge a gas toward a peripheral portion of the substrate on the first base.

9. The electrostatic chuck of claim 8, wherein the discharge port is configured to open on an upper surface of the second base, and
wherein the gas discharger includes a flow controller provided on the upper surface of the second base and configured to control a flow of the gas discharged from the discharge port.

10. The electrostatic chuck of claim 9, wherein the flow controller forms a flow path through which the gas passes between the flow controller and the first base, and
wherein the flow path includes, at an upstream side or a downstream side of the flow path, a relief portion configured to reduce a flow velocity of the gas and direct the gas in a direction away from the substrate.

11. The electrostatic chuck of claim 9, wherein, when the discharge port is defined as a first discharge port, the gas discharger further includes a second discharge port configured to discharge the gas toward a peripheral portion of the flow controller.

12. The electrostatic chuck of claim 1, further comprising:
a third base disposed on a lower surface side of the second base; and
a fourth base disposed on a lower surface side of the third base,
wherein the third base is made of the composite material, and
wherein the fourth base is made of a material having a coefficient of thermal expansion close to the coefficient of thermal expansion of the composite material.

13. The electrostatic chuck of claim 1, further comprising a heating portion provided in the second base and configured to heat the substrate.

14. The electrostatic chuck of claim 1, wherein the electrostatic chuck is used to form a ruthenium film on the substrate.

15. A substrate processing apparatus, comprising:
an electrostatic chuck configured to electrostatically attract a substrate; and
a processing chamber in which the electrostatic chuck is accommodated and in which a film formation process is performed on the substrate while the substrate is electrostatically attracted to the electrostatic chuck,
wherein the electrostatic chuck includes:
a first base having an upper surface on which the substrate is placed; and
a second base disposed on a lower surface side of the first base,
wherein the first base includes a plate-shaped member made of a composite material of metal and ceramics, and an insulating layer having insulating properties and formed in a layered structure on an upper surface of the plate-shaped member, and
wherein the second base is made of a material having a coefficient of thermal expansion close to a coefficient of thermal expansion of the composite material.

16. A substrate processing method of performing a film formation process on a substrate,
wherein, when performing the film formation process on the substrate, the substrate is electrostatically attracted to an electrostatic chuck,
wherein the electrostatic chuck includes:
a first base having an upper surface on which the substrate is placed; and
a second base disposed on a lower surface side of the first base,
wherein the first base includes a plate-shaped member made of a composite material of metal and ceramics, and an insulating layer having insulating properties and formed in a layered structure on an upper surface of the plate-shaped member, and
wherein the second base is made of a material having a coefficient of thermal expansion close to a coefficient of thermal expansion of the composite material.
